(19) United States
(12) Patent Application Publication
(10) Pub. No.: US 2018/0359864 A1
(43) Pub. Date: Dec. 13, 2018

(54) METAL ELECTRODE LEADLESS FACE (MELF) DEVICE CRADLE

(71) Applicant: PITYU CONTROLS INC., Edmontion (CA)

(72) Inventor: Stevan DOBI, Edmonton (CA)

(21) Appl. No.: 16/003,474

(22) Filed: Jun. 8, 2018

Related U.S. Application Data
(60) Provisional application No. 62/517,689, filed on Jun. 9, 2017.

(51) Int. Cl. H05K 3/34; H05K 1/18; B23K 1/00

(52) U.S. Cl. CPC H05K 3/3442; H05K 1/181; B23K 1/0016; H05K 2201/09381; B23K 2101/42; H05K 2201/10583; H05K 2203/048; H05K 2201/10174; H05K 2201/10022; H05K 2201/09427

(57) ABSTRACT

A cradle for a metal electrode leadless face (MELF) device is provided. The cradle can include at least one pad, such as a solder pad, to be connected to a printed circuit board (PCB) or similar board. The pad can be configured to receive a MELF device. Such a configuration can improve positioning and alignment of the MELF device and prevent or reduce movement of the MELF device prior to or during soldering. The pad can include boundaries to engage the MELF device for alignment and to prevent or reduce movement. The boundaries of the pad can include inlets, extensions, troughs, borders, and/or other features to engage the MELF device. Boards including such cradles are also provided. Further, methods of installing a MELF device on a board using a cradle are also provided.

### CROSS REFERENCE TO RELATED APPLICATIONS:

This application claims priority of U.S. Provisional Patent Application Ser. No. 62/517,689, entitled “Metal Electrode Leadless Face (MELF) Device Cradle”, filed Jun. 9, 2017, which is hereby incorporated by reference herein in its entirety.

### TECHNICAL FIELD

This disclosure provides a metal electrode leadless face (MELF) device cradle, more specifically a MELF device cradle for use with a printed circuit board (PCB) or similar board.

### BACKGROUND

Metal electrode leadless face (MELF) is a type of leadless, generally cylindrical, electronic surface mount device that is metallized at its ends. MELF devices, such as MELF diodes and MELF resistors are known to have certain advantages and disadvantages.

In particular, MELF devices are known to have handling difficulties. Because of their cylindrical shape and small size, in some cases these components can easily roll off the workbench or circuit board before they have been soldered into place. The problem is so persistent that a humorous alternate meaning for the MELF acronym is: Most End up Lying on the Floor. Additionally, MELF components are sometimes called a “roll away” package.

Known means to address the handling problems have their shortcomings. For example, means which apply additional pressure are problematic as they can cause damage to fragile MELF devices such as glass diodes. Further, when manually assembling a printed circuit board (PCB) or similar boards using tweezers the pressure at the end of tweezers can often cause a MELF component to slip and shoot out the ends, thereby making their placement more difficult, compared to other flat component packages.

Therefore, there remains a need for devices and methods that can overcome the shortcomings of the prior art.

### SUMMARY

A cradle for a metal electrode leadless face (MELF) device is provided. The cradle can include at least one pad, such as a solder pad, to be connected to a printed circuit board (PCB) or similar board. The pad can be configured to receive a MELF device. Such a configuration can improve positioning and alignment of the MELF device and prevent or reduce movement of the MELF device prior to or during soldering. The pad can include boundaries to engage the MELF device for alignment and to prevent or reduce movement. The boundaries of the pad can include inlets, extensions, troughs, borders, and/or other features to engage the MELF device. Boards including such cradles are also provided. Further, methods of installing a MELF device on a board using a cradle are also provided.

Broadly stated, in some embodiments, a cradle is provided for a metal electrode leadless face (MELF) device, the cradle comprising: at least one pad configured to receive the MELF device; wherein movement of the MELF device is restricted when received by the pad.

Broadly stated, in some embodiments, a board is provided, a board comprising a cradle as described herein.

Broadly stated, in some embodiments, a method is provided for positioning a metal electrode leadless face (MELF) device on a board, the method comprising: placing a cradle on the board; and receiving the MELF device into the cradle.

The term MELF as used herein is not a term of limitation and contemplates changes or variations in industry nomenclature that may refer to similar devices by other terms or names. For the purposes of this disclosure and the following claims, the term MELF device is inclusive of these other terms and names. Further the term MELF device can refer to generally cylindrical devices, but can also refer to other shaped and designed devices that may have difficulties with positioning, alignment, and/or remaining stationary, for example, but not limited to curved, ovular, oblong, circular, and/or spherical device shapes.

### DESCRIPTION OF DRAWINGS

FIG. 1A is a perspective view of an embodiment of a prior art metal electrode leadless face (MELF) device;

FIG. 1B is a side elevation view of the prior art MELF device of FIG. 1A;

FIG. 1C is a front elevation view of the prior art MELF device of FIG. 1A;

FIG. 2 an electronic schematic depicting an embodiment of a board, for example a printed circuit board (PCB) including embodiments of a cradle for a MELF device;

FIG. 3A is a perspective view of an embodiment of a cradle for receiving a MELF device;

FIG. 3B is a top planar view of the cradle of FIG. 3A;

FIG. 4A is a top planar view of an embodiment of a cradle for receiving a MELF device, showing section lines A-A and C-C;

FIG. 4B is a elevational cross-section view of the cradle of FIG. 4A, along the section lines A-A;

FIG. 4C is an elevational cross-section view of the cradle of FIG. 4A, along the section lines C-C;

FIG. 5A is a perspective view depicting an embodiment of a cradle in use, cradling an embodiment of a MELF device;

FIG. 5B is a top planar view of the cradle of FIG. 5A in use, cradling the MELF device of FIG. 5A;

FIG. 5C is a front elevation view of the cradle of FIG. 5A in use, cradling the MELF device of FIG. 5A; and

FIG. 5D is a side elevation view of the cradle of FIG. 5A in use, cradling the MELF device of FIG. 5A, and showing section lines A-A; and

FIG. 5E is a front elevational cross-section view of the cradle of FIG. 5A in use, cradling the MELF device of FIG. 5A, along the FIG. 5A section lines A-A.

### DETAILED DESCRIPTION

A cradle for a metal electrode leadless face (MELF) device is provided. The cradle can include at least one pad, such as a solder pad, to be connected to a printed circuit board (PCB) or similar board. The pad can be configured to receive a MELF device. Such a configuration can improve positioning and alignment of the MELF device and prevent or reduce movement of the MELF device prior to or during soldering. The pad can include boundaries to engage the MELF device for alignment and to prevent or reduce movement. The boundaries of the pad can include inlets, extensions, troughs, borders, and/or other features to engage the MELF device. Boards including such cradles are also provided. Further, methods of installing a MELF device on a board using a cradle are also provided.

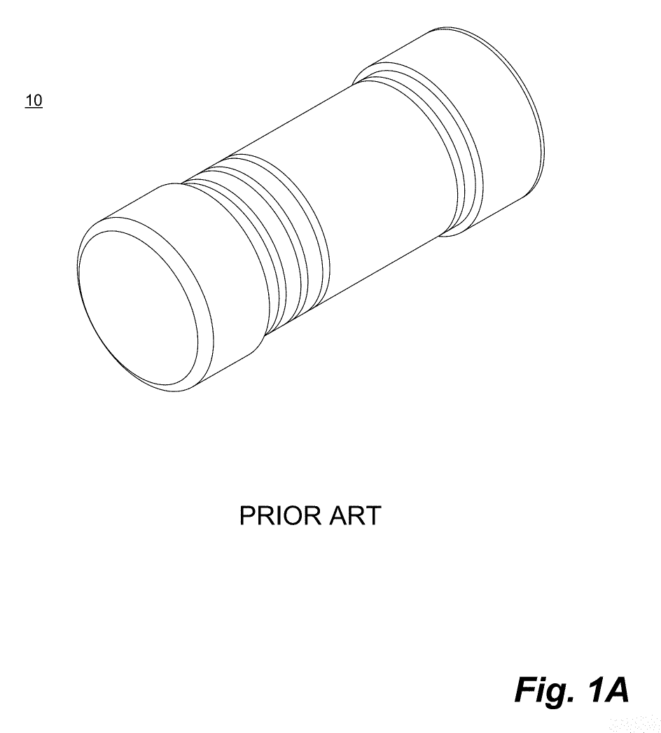

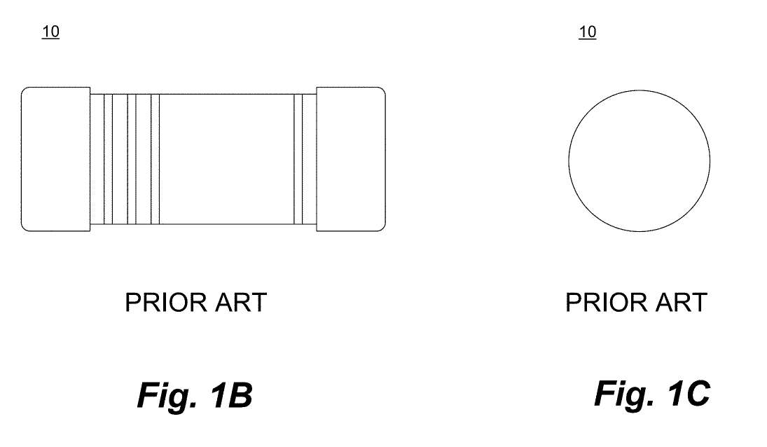

Referring to FIGS. 1A, 1B, and 1C, a prior art embodiment of a MELF device 10 is shown in a perspective view, side elevation view, and front elevation view, respectively. In some embodiments, MELF device 10 can be MELF diodes and/or MELF resistors, although it would be appreciated that other MELF devices can be included. It becomes apparent that a substantially cylindrical shape, such as that depicted would lead to the MELF devices 10 rolling and moving when placed on a flat service.

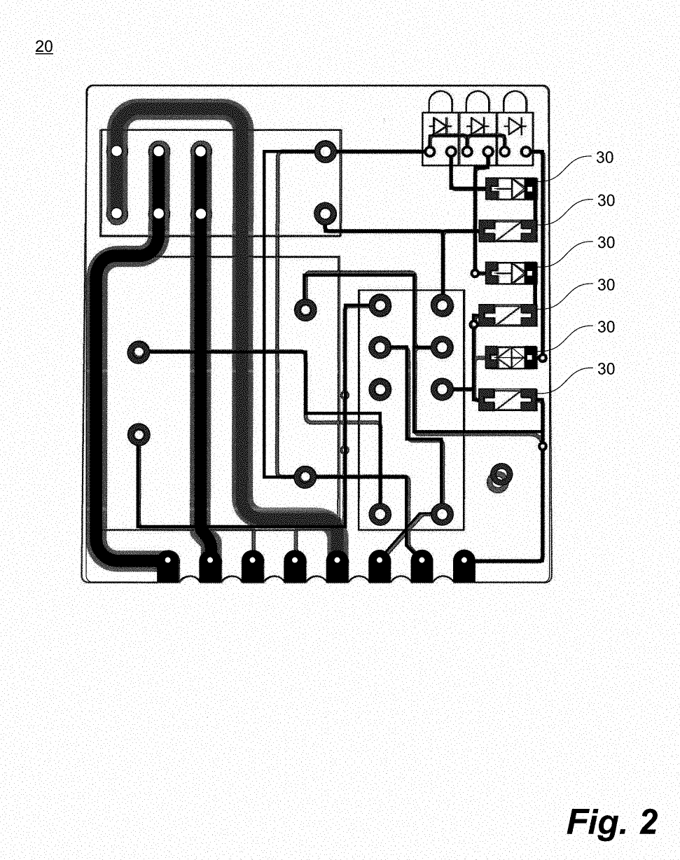

Referring to FIG. 2, an embodiment of a board 20 is shown. In some embodiments, board 20 can be a circuit board. In some embodiments, board 20 can be a PCB. Board 20 can include one or more cradles 30 for receiving a MELF device 10. Cradle 30 can be used to position and/or align MELF device on board 20 prior to soldering. Cradling of MELF devices 10 by cradle 30 can reduce or prevent unwanted movement of MELF device 10. In some cases, cradle 30 can prevent MELF device from rolling, and potentially rolling off of board 20.

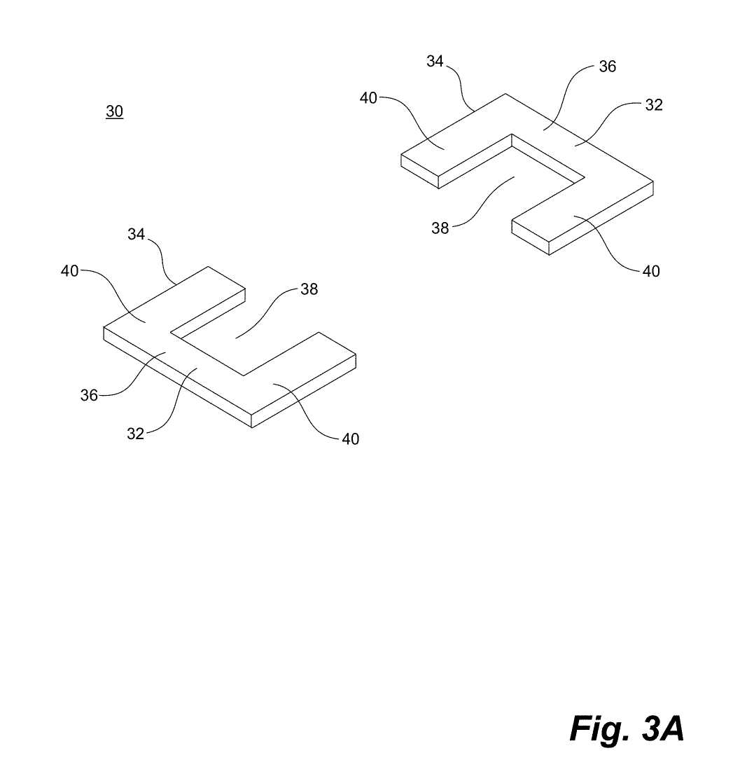

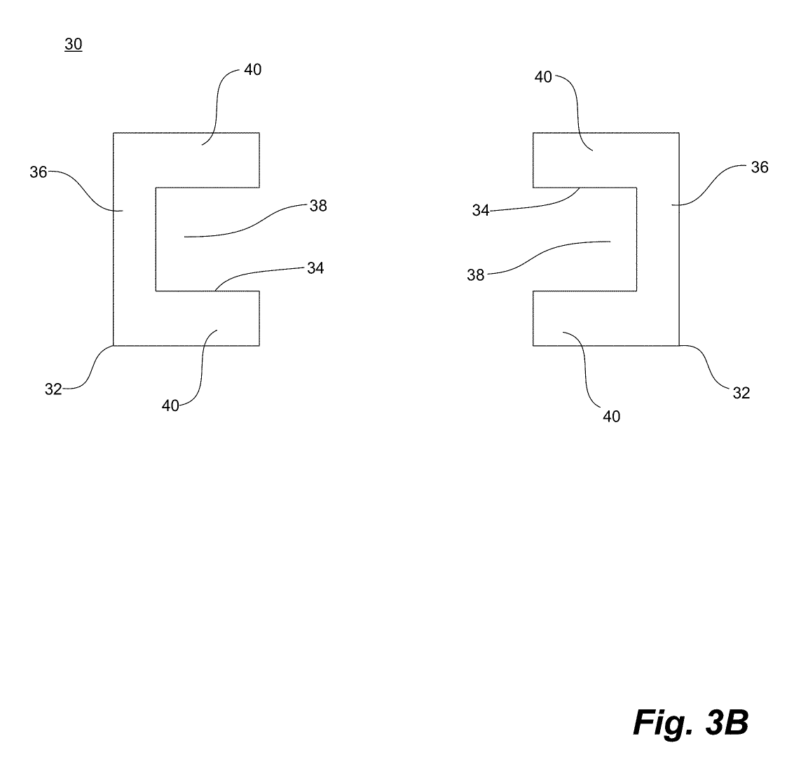

Referring now to FIGS. 3A and 3B, an embodiment of a cradle 30 for receiving a MELF device 10 is shown. Cradle 30, can be shaped and/or configured to receive MELF device 10 for positioning, alignment, and prevention of unwanted MELF device 10 movement. Cradle 30 can comprise at least one pad 32. In some embodiments, pad 32 can be a soldering pad. In some embodiments, pad 32 can be copper, although it would be appreciated that other materials, such as conductive materials can be used.

Pad 32 can include boundaries 34 and in some configurations can include a body 36, and at least one inlet 38 and/or extension 40. Boundaries 34 can engage MELF device 10 and the configuration of body 36 and/or inlets 38 and/or extensions 40 can position MELF device 10 and prevent unwanted movement of MELF device 10. It would be appreciated that pad 32 shapes and configurations other than those shown could be used. In some embodiments, troughs in pad 32 can be used to receive MELF device 10.

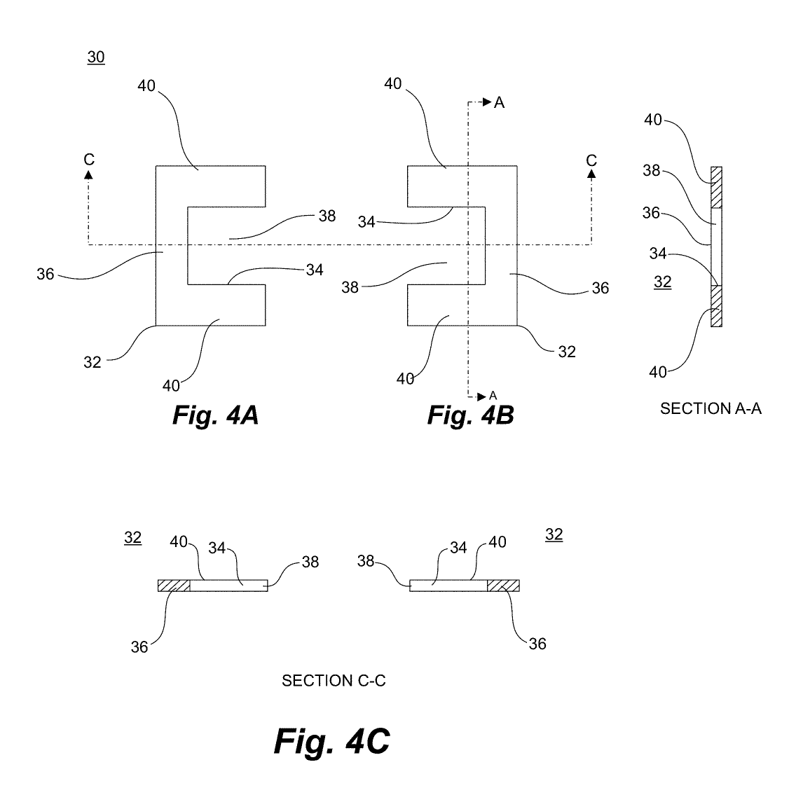

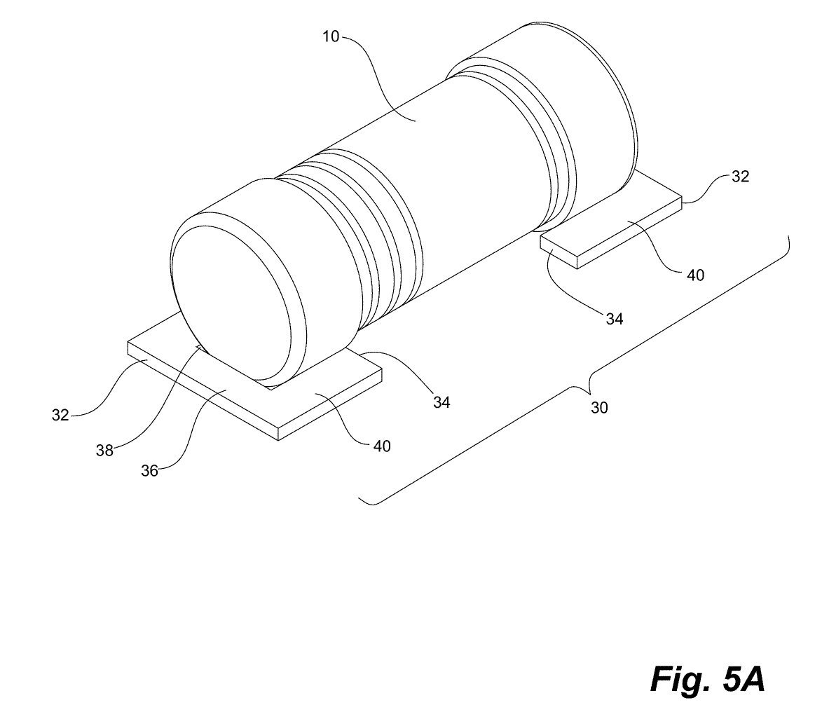

FIGS. 4A, 4B, and 4C demonstrate cross sectional views of an embodiment of cradle 30 for receiving MELF device 10.

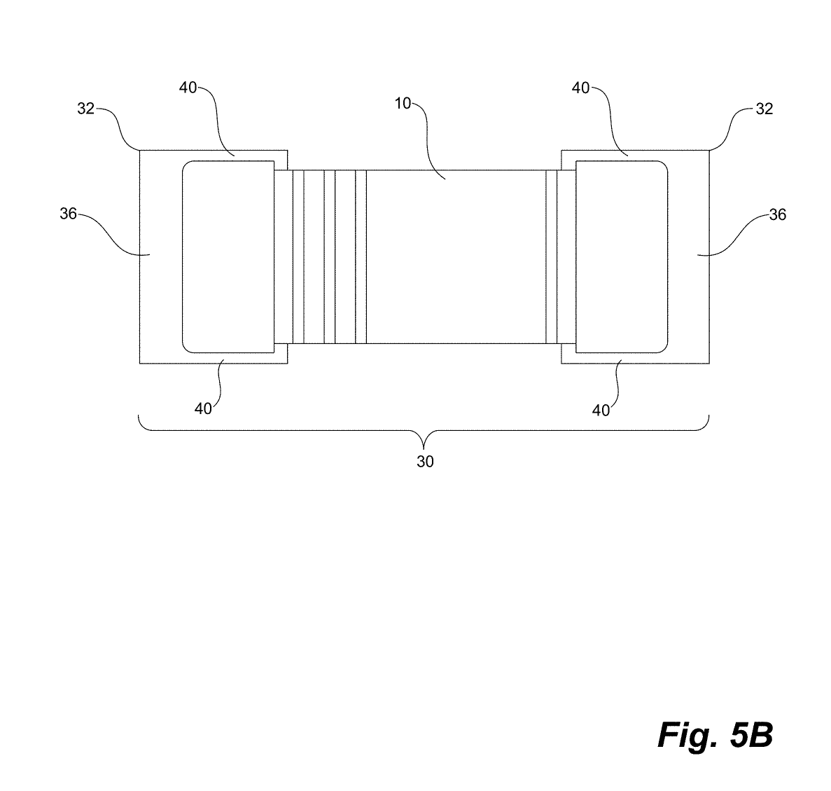

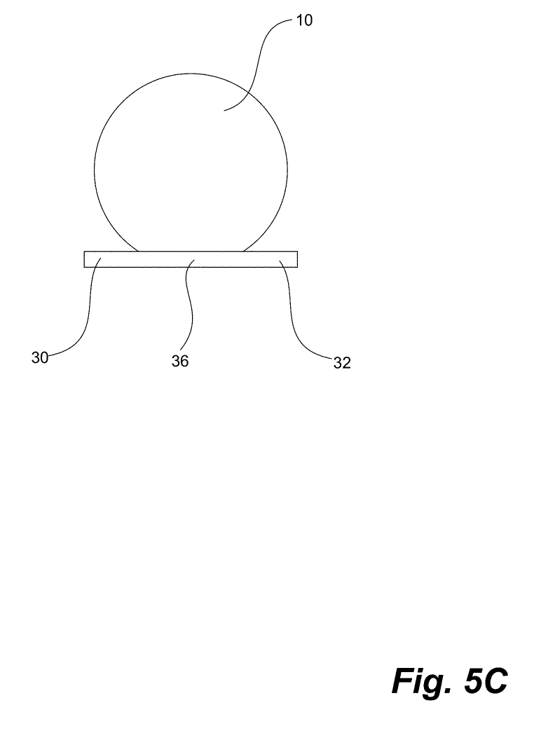

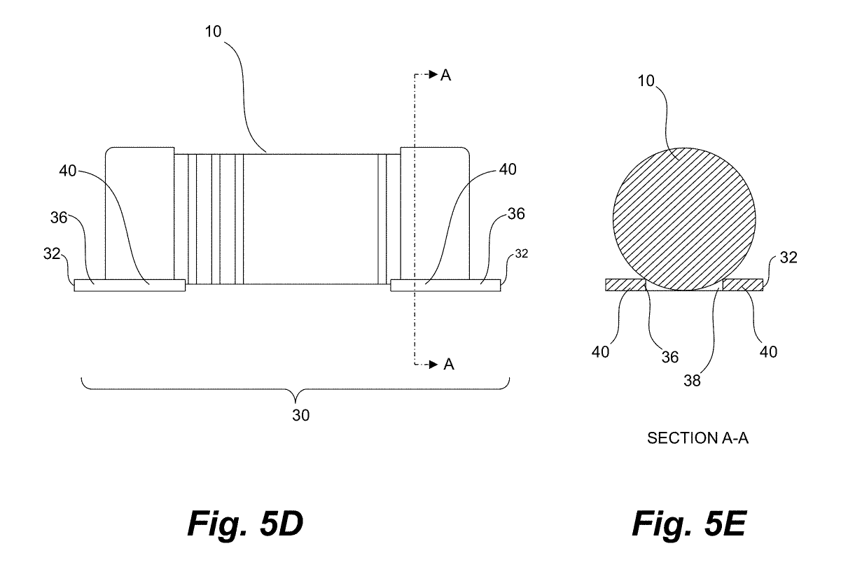

FIGS. 5A, 5B, 5C, 5D, and 5E depict an embodiment of cradle 30 in use, cradling an embodiment of MELF device 10. As shown in FIGS. 5C and 5E, MELF device 10 can become nested in cradle 30 and boundaries 34 can restrict the movement of MELF device 10.

Once MELF device 10 is received by cradle 30 on board 20, the concern for unwanted movement of MELF device 10 is ameliorated, and MELF device 10 can then be soldered, or otherwise fixed to board 20.

Although particular embodiments have been shown and described, it will be appreciated by those skilled in the art that various changes and modifications might be made without departing from the scope of the invention. The terms and expressions used in the preceding specification have been used herein as terms of description and not of limitation, and there is no intention in the use of such terms and expressions of excluding equivalents of the features shown and described or portions thereof, it being recognized that the invention is defined and limited only by the claims that follow.

We claim:

1. A cradle for a metal electrode leadless face (MELF) device, the cradle comprising:
at least one pad configured to receive the MELF device;
wherein movement of the MELF device is restricted when received by the pad.

2. The cradle of claim 1 wherein the pad is a soldering pad.

3. The cradle of claim 1 wherein the pad is copper.

4. The cradle of claim 1 wherein the pad comprises boundaries for engaging the MELF device.

5. The cradle of claim 1 wherein the pad comprises an inlet for receiving the MELF device.

6. The cradle of claim 1 wherein the pad comprises a trough for receiving the MELF device.

7. The cradle of claim 1 wherein the pad comprises an extension for bordering the MELF device.

8. The cradle of claim 1 wherein the pad comprises a border for bordering the MELF device.

9. A board comprising the cradle of claim 1.

10. The board of claim 9 wherein the board is a circuit board.

11. The board of claim 10 wherein the circuit board is a printed circuit board (PCB).

12. A method of positioning a metal electrode leadless face (MELF) device on a board, the method comprising:
placing a cradle on the board; and
receiving the MELF device into the cradle.

13. The method of claim 12 further comprising attaching the received MELF device to the board.

14. The method of claim 13 wherein the attaching step comprises soldering the received MELF device to the board.

15. The method of claim 12 wherein the cradle comprises:
at least one pad configured to receive the MELF device;
wherein movement of the MELF device is restricted when received by the pad.
